(19) United States
(12) Patent Application Publication
(10) Pub. No.: US 2025/0084280 A1
(43) Pub. Date: Mar. 13, 2025

(54) MOLYBDENUM CHEMICAL MECHANICAL POLISHING COMPOUNDS AND METHODS OF USE THEREOF

(71) Applicant: FUJIMI INCORPORATED, Aichi (JP)

(72) Inventors: Shogo Onishi, Tualatin, OR (US); Glenn Whitener, Tualatin, OR (US)

(21) Appl. No.: 18/818,832

(22) Filed: Aug. 29, 2024

Related U.S. Application Data
(60) Provisional application No. 63/537,635, filed on Sep. 11, 2023.

(51) Int. Cl. C09G 1/02; C09K 13/00

(52) U.S. Cl. CPC C09G 1/02; C09K 13/00

(57) ABSTRACT

The present disclosure relates to chemical mechanical polishing (CMP) compositions comprising a first and second molybdenum static etching rate suppressor, an anionic silica abrasive, and an oxidizer.

The first molybdenum static etching rate suppressor is a phosphate-containing polyethylene surfactant or a sulfate-containing polyethylene surfactant, and the second molybdenum static etching rate suppressor is a basic amino acid, and this combination provides advantageous properties such as high molybdenum removal rate while also exhibiting a low molybdenum static etching rate, thus providing compositions well suited for polishing a molybdenum surface.

### TECHNICAL FIELD

The present disclosure relates to chemical mechanical polishing (CMP) compositions comprising a first and second molybdenum static etching rate suppressor, an anionic silica abrasive, and an oxidizer. More particularly, the first molybdenum static etching rate suppressor is a phosphate-containing polyethylene surfactant or a sulfate-containing polyethylene surfactant, and the second molybdenum static etching rate suppressor is a basic amino acid. This combination provides advantageous properties such as high molybdenum removal rate while also exhibiting a low molybdenum static etching rate, thus providing compositions well suited for polishing a molybdenum surface.

### BACKGROUND ART

CMP is a process in which material is removed from a surface of a substrate (such as a semiconductor wafer) and the surface is polished (planarized) by coupling a physical process, such as abrasion, with a chemical process, such as oxidation or chelation. In its most rudimentary form, CMP involves applying a slurry to the surface of the substrate or a polishing pad that polishes the substrate. This process achieves both the removal of unwanted material and planarization of the surface of the substrate. It is not desirable for the removal or polishing process to be purely physical or purely chemical, but rather comprise a synergistic combination of both.

CMP is used on a large variety of objects, examples of which include silicon dioxide (SiO₂) in inter-layer or buried dielectrics; metals such as aluminum (Al), copper (Cu), and tungsten (W) in wiring layers or plugs connecting to such a wiring layer; a barrier metal layer such as tantalum (Ta), tantalum nitride (TaN), and titanium (Ti); polysilicon for use as a trench capacitor; and molybdenum, which is used in a wide range of applications.

Molybdenum may be used in a variety of industrial applications, including microelectronic devices such as connectors, photo masks, and semiconductor device manufacture. In such applications, molybdenum is often initially utilized in an excess amount. This requires that some molybdenum must be removed in order to provide a substrate with suitable surface properties.

When polishing a molybdenum-containing substrate, the CMP process typically employs abrasive particles, which are suspended in a liquid medium, such as water, sometimes with the aid of a surfactant as a dispersing agent. Polishing of metallic molybdenum surfaces often is accomplished using abrasives of varying sizes to obtain a desired surface roughness. Currently used abrasives generally require multiple steps to polish molybdenum surfaces, which can mean using multiple machines and/or parts and abrasive changes, which can adversely affect the processing time for each part.

Thus, developing CMP processes that do not require some of the conditions mentioned above while still providing beneficial polishing properties (e.g., high polishing speeds and/or removal rates) would be highly desirable.

### SUMMARY OF INVENTION

In accordance with the purpose(s) of the currently disclosed subject matter, it is an object of the present invention to provide a composition for polishing substrates, such as those containing molybdenum, that facilitate improvement in polishing speeds when using CMP. Another object of the present invention is to provide a method having a low static etching rate for such molybdenum-containing substrates.

Accordingly, the presently disclosed subject matter in one aspect relates to a polishing composition comprising an anionic abrasive, a first molybdenum static etching rate suppressor, a second molybdenum static etching rate suppressor, and an oxidizer, wherein the first molybdenum static etching rate suppressor is a phosphate-containing polyethylene surfactant or a sulfate-containing polyethylene surfactant, and the second molybdenum static etching rate suppressor is a basic amino acid.

In another aspect, the subject matter described herein is directed to a method for polishing a substrate, the method comprising the steps of: (a) providing a polishing composition as disclosed herein; (b) providing a substrate, wherein the substrate comprises a molybdenum-containing layer; and (c) polishing the substrate with the polishing composition to provide a polished substrate.

### DETAILED DESCRIPTION

The present invention can be understood more readily by reference to the following detailed description of the invention and the examples included therein.

The present invention now will be described in detail hereinafter. Herein, “X to Y” is used to mean that it includes the values set forth at the beginning and the end of that phrase (X and Y) as the lower limit and the upper limit, and it means “not less than X and not more than Y”. When the expression “X to Y” is described in more than one time, for example when “X1 to Y1, or X2 to Y2” is described, the disclosure specifying each such value as the upper limit, the disclosure specifying each such value as the lower limit, and the combinations of such upper limits and lower limits are all disclosed (i.e., they can be legitimate supporting evidence for amendments). Specifically, all the amendments for specifying the range as “not less than X1”, “not more than Y2”, “not more than X1”, “not less than Y2”, “X1 to X2”, “X1 to Y2” and the like have to be regarded as legitimate. Furthermore, when the characteristics and aspects of the present disclosure are described in terms of Markush group, those skilled in the art will appreciate that the present disclosure is described in terms of any individual constituent of the Markush group or a subgroup of the constituents. Unless otherwise stated, operations and measurements of physical properties are conducted under the condition of room temperature (20 to 25° C.)/relative humidity of 40 to 50% RH. Concentrations described herein may be the concentrations at POU (point of use) or may be the concentrations before being diluted to the POU concentration. Dilution ratios may be 2 to 10. It should be understood that combinations of all embodiments and descriptions disclosed herein are disclosed in this application. Thus, it should be understood that such combinations can be supporting evidence for amendments. When a content or a concentration of each component is described, the content or the concentration may be the sum of those for two or more species in the case that two or more species are contained in the component.

Before the present compounds, compositions, articles, systems, devices, and/or methods are disclosed and described, it is to be understood that they are not limited to specific synthetic methods unless otherwise specified, or to particular components unless otherwise specified, as such may, of course, vary. It is also to be understood that the terminology used herein is for describing particular aspects only, and is not intended to be limiting. Although, any methods and materials that are similar or equivalent to those described herein can be used in the practice or testing of the present invention, example methods and materials are now described.

Described herein are polishing compositions comprising an anionic abrasive, a first molybdenum static etching rate suppressor, a second molybdenum static etching rate suppressor, and an oxidizer. These polishing compositions are intended for polishing a substrate where the polishing compositions exhibit at least one benefit such as: 1) a low molybdenum static etching rate (SER); 2) a high molybdenum removal rate (RR); 3) a high Mo(RR):Mo(SER) ratio; 4) a low chloride ion concentration; and 5) a high composition stability.

The molybdenum (Mo) static etching rate (SER), molybdenum (Mo) removal rate (RR), and Mo(RR):Mo(SER) selectivity of the polishing compositions described herein are key properties. Compositions exhibiting these key properties may be obtained by use of specific components in requisite amounts. For example, in some embodiments, a polishing composition comprising an anionic silica abrasive, a first molybdenum static etching rate suppressor, a second molybdenum static etching rate suppressor, an oxidizer, and a pH-adjusting agent has been found to provide a high Mo removal rate (RR) and/or high Mo(RR):Mo(SER) selectivity, wherein the concentrations of each component of the polishing composition must be present in specific amounts to provide a high rate of Mo removal and a low Mo static etching rate.

The polishing compositions described herein have uses such as, but not limited to, the CMP of molybdenum-containing substrates.

### A. DEFINITIONS

Listed below are definitions of various terms used to describe this invention. These definitions apply to the terms as they are used throughout this specification, unless otherwise limited in specific instances, either individually or as part of a larger group.

As used in the specification and the appended claims, the singular forms “a,” “an” and “the” include plural referents unless the context clearly dictates otherwise. Thus, for example, reference to “an abrasive” or “a pH-adjusting agent” includes mixtures of two or more such abrasives or pH-adjusting agents.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. It will also be understood that there are a number of values disclosed herein, and that each value is herein disclosed as “about” that particular value in addition to the value itself. For example, if the value “10” is disclosed, then “about 10” is also disclosed. It will also be understood that each unit between two particular units is also disclosed. For example, if 10 and 15 are disclosed, then 11, 12, 13, and 14 are also disclosed. Herein, “about X” (X is a numerical value) means that it further includes the range of X±10% or X±5%, and in referring to ±10% by way of example, it means X±0.9 to X±1.1. Furthermore, “about X” may be X itself.

As used herein, the term “alkyl” refers to a straight or branched chain hydrocarbon containing from 1 to 25 carbon atoms. Representative examples of alkyl include, but are not limited to, methyl, ethyl, n-propyl, isopropyl, n-butyl, sec-butyl, isobutyl, tert-butyl, n-pentyl, isopentyl, neopentyl, n-hexyl, 3-methylhexyl, 2,2-dimethylpentyl, 2,3-dimethylpentyl, n-heptyl, n-octyl, n-nonyl, n-decyl, and the like.

The term “alkenyl” as used herein is a hydrocarbon group of 2 to 25 carbon atoms with a structural formula containing at least one carbon-carbon double bond. Non-limiting examples of alkenyls include C2-18 alkenyl, C2-12 alkenyl, C2-8 alkenyl, C2-6 alkenyl, and C2-3 alkenyl.

As used herein, the term “aryl” refers to a hydrocarbon monocyclic, bicyclic or tricyclic aromatic ring system. Aryl groups may be optionally substituted with one or more substituents. In one embodiment, 0, 1, 2, 3, 4, 5 or 6 atoms of each ring of an aryl group may be substituted by a substituent. Examples of aryl groups include phenyl, naphthyl, anthracenyl, fluorenyl, indenyl, azulenyl, and the like.

References in the specification and concluding claims to parts by weight of a particular element or component in a composition denote the weight relationship between the element or component and any other elements or components in the composition or article for which a part by weight is expressed. Thus, in a compound containing 2 parts by weight of component “X” and 5 parts by weight of component “Y,” “X and Y” are present at a weight ratio of 2:5, and are present in such ratio regardless of whether additional components are contained in the compositions.

A weight percent (wt %) of a component, unless specifically stated to the contrary, is based on the total weight of the vehicle or composition in which the component is included.

As used herein, the terms “optional” and “optionally” mean that the subsequently described event or circumstance can or cannot occur, and that the description includes instances where said event or circumstance occurs and instances where it does not.

### B. POLISHING COMPOSITION

A polishing composition may be also referred to as a polishing slurry.

The fundamental mechanism of CMP is to soften a surface layer by chemical reaction and then remove the softened layer by mechanical force with abrasive particles. However, the role of CMP is not only material removal, but also planarization, surface smoothening, uniformity control, defect reduction and more. Semiconductor yield enhancement is thus influenced by CMP processing.

In polishing compositions for use with molybdenum (Mo)-containing substrates, one key performance metric is a high Mo removal rate, which provides a minimal Mo static etching rate. Polishing compositions with high Mo removal rate and/or high Mo(RR):Mo(SER) selectivity are ideally formulated at pH from about 2 to about 4. These and other aspects will be discussed further herein.

In light of the complexity surrounding the various mechanisms of Mo removal rates, it is critical to identify compositions enabling a high Mo removal rate, while simultaneously enabling a low Mo static etching rate, and thus providing high Mo(RR):Mo(SER) selectivity.

It was surprising and unexpected to discover that the polishing compositions disclosed herein are able to achieve high Mo removal rates and low Mo static etching rates when two different Mo static etching rate suppressors were present in the polishing compositions disclosed herein. In particular, polishing compositions having an anionic silica abrasive, an iodine-containing oxidizer, and a first Mo static etching rate suppressor selected from a phosphate-containing and a sulfate-containing polyethylene surfactant and a second Mo static etching rate suppressor selected from a basic amino acid exhibited such beneficial polishing properties.

Thus, key aspects of the polishing compositions described herein include, but are not limited to: 1) high Mo removal rates (RR); 2) low Mo static etching rates (SER); 3) high Mo(RR):Mo(SER) ratio; and 4) a key pH. As described herein, the combination of specific components in specified amounts is key to obtaining these desired properties.

### 1. Abrasive

The polishing composition described herein contains an abrasive. The abrasive is typically a metal oxide abrasive preferably selected from the group consisting of silica, alumina, titania, zirconia, germania, ceria and mixtures thereof. In some embodiments, the abrasive is silica. In a further embodiment, the abrasive is colloidal silica.

In some embodiments, the abrasive is either a commercial product or a synthetic product. As a method for producing colloidal silica, for example, a sodium silicate method and a sol-gel method can be exemplified, and colloidal silica produced by either method can be used preferably as the abrasive of the present invention. However, in the light of reducing metal impurities, colloidal silica produced by the sol-gel method, which can produce colloidal silica at high purity, is more preferable.

The abrasive can have any suitable particle size. In some embodiments, the grains of the abrasives used in the present invention have an average primary particle size (“PPS”) of 10 nm or more and 100 nm or less. In some embodiments, the grains of the abrasives used in the present invention have an average primary particles size of from about 10 nm to about 100 nm, from about 10 nm to about 70 nm, from about 15 nm to about 60 nm, from about 20 nm to about 50 nm, from about 25 nm to about 45 nm, from about 30 nm to about 40 nm, or from about 32 nm to about 38 nm. In some embodiments, the grains of the abrasives used in the present invention have an average primary particles size of from about 12 nm to about 92 nm, from about 32 nm to about 87 nm, from about 53 nm to about 77 nm, from about 60 nm to about 75 nm, from about 65 nm to about 75 nm or from about 68 nm to about 72 nm.

A lower limit of the average primary particle size of the abrasive grains is preferably 25 nm or more, is more preferably 30 nm or more, is more preferably 50 nm or more, is more preferably 60 nm or more and is further preferably 65 nm or more. Further, an upper limit of the average primary particle size of the abrasive grains is preferably less than 75 nm, is more preferably 70 nm or less, is more preferably 50 nm or less, is more preferably 40 nm or less, and is further preferably 35 nm or less. In some embodiments, the grains of the abrasives used in the present invention have an average primary particle size of 5 nm or more, 6 nm or more, 8 nm or more, 10 nm or more, more than 10 nm, 15 nm or more, 20 nm or more, more than 20 nm, 22 nm or more, 24 nm or more, 26 nm or more, or 28 nm or more. In some embodiments, the grains of the abrasives used in the present invention have an average primary particle size of 90 nm or less, 80 nm or less, 70 nm or less, less than 70 nm, 65 nm or less, 60 nm or less, 55 nm or less, 50 nm or less, 45 nm or less, or 40 nm or less. In some embodiments, the grains of the abrasives used in the present invention have an average primary particle size of more than 20 nm and less than 70 nm.

An average primary particle size of abrasive grains can be measured by a field emission scanning electron microscope (FE-SEM) (manufacturer and model number: Hitachi High-Tech Corporation, S-4800).

The grains of the abrasive can have any suitable mean particle size. For example, the grains of the abrasive can have an average mean particle size (“MPS”) of from about 10 nm to about 150 nm, from about 20 nm to about 120 nm, from about 30 nm to about 110 nm, from about 40 nm to about 100 nm, from about 45 nm to about 90 nm, from about 50 nm to about 80 nm, from about 60 nm to about 75 nm, or from about 65 nm to about 78 nm. In some embodiments, the grains of the abrasive can have an average mean particle size of from about 50 nm to about 150 nm, from about 75 nm to about 140 nm, from about 100 nm to about 130 nm, from about 110 nm to about 130 nm, or from about 115 nm to about 125 nm.

In some embodiments, the grains of the abrasive can have an average mean particle size of about 10 nm or more, about 25 nm or more, 50 nm or more, 70 nm or more, 100 nm or more, or about 120 nm or more. Alternatively, or in addition, the grains of the abrasive can have an average mean particle size of about 150 nm or less, about 120 nm or less, about 100 nm or less, about 70 nm or less, about 50 nm or less, or about 30 nm or less. A particle size analyzer (Horiba Particle Size Distribution tool) can measure the average mean particle size of the abrasive grains. In some embodiments, the grains of the abrasive can have an average mean particle size of 15 nm or more, 20 nm or more, 23 nm or more, more than 23 nm, 30 nm or more, 35 nm or more, 40 nm or more, 46 nm or more, more than 46 nm, 50 nm or more, 55 nm or more, 60 nm or more, or 65 nm or more. In some embodiments, the grains of the abrasive can have an average mean particle size of 140 nm or less, 130 nm or less, 120 nm or less, less than 120 nm, 110 nm or less, 100 nm or less, 90 nm or less, or 80 nm or less. In some embodiments, the grains of the abrasive can have an average mean particle size of more than 46 nm and less than 120 nm.

The abrasive can have any suitable surface area. For example, the abrasive can have an average BET surface area of about 50 m²/g or more, about 60 m²/g or more, about 70 m²/g or more, about 80 m²/g or more, about 90 m²/g or more, about 100 m²/g or more, about 110 m²/g or more, or about 120 m²/g or more. Alternatively, or in addition, the abrasive can have an average surface area of about 130 m²/g or less, about 120 m²/g or less, about 110 m²/g or less, about 100 m²/g or less, about 90 m²/g or less, about 80 m²/g or less, about 70 m²/g or less, about 60 m²/g or less, more, or about 50 m²/g or less. In some embodiments, the abrasive can have an average surface area in a range from about 30 m²/g to about 150 m²/g, from about 40 m²/g to about 140 m²/g, from about 50 m²/g about 130 m²/g, from about 60 m²/g to about 125 m²/g, from about 65 m²/g to about 120 m²/g, from about 70 m²/g to about 120 m²/g, from about 75 m²/g to about 115 m²/g, from about 80 m²/g to about 110 m²/g, or from about 85 m²/g to about 110 m²/g.

The silanol group density on the silica surface of the abrasive can vary. In some embodiments, the average silanol group density on the silica surface of the abrasive grains contained in the polishing composition of the present invention is 6.0 nm⁻² or less. If the average silanol group density is more than 6.0 nm⁻², hardness of the abrasive grains is low, and the polishing speed is accordingly lowered. The unit “count/nm²” can be herein also expressed as “nm⁻²”.

The average silanol group density on the surface of the abrasive grains is preferably 5.7 nm⁻² or less, and is more preferably 5.5 nm⁻² or less. The average silanol group density on the surface of the abrasive grains is 1.0 nm⁻² or more, 2.0 nm⁻² or more, 3.0 nm⁻² or more, 4.0 nm⁻² or more, and is 5.0 nm⁻² or more.

In some embodiments, the average silanol group density on the surface of the abrasive grains is from about 1 nm⁻² to about 7 nm⁻², from about 1.3 nm 2 to about 6.7 nm⁻², from about 1.5 nm⁻² to about 6.5 nm⁻², from about 1.6 nm⁻² to about 5.5 nm⁻². In some embodiments, the average silanol group density on the surface of the abrasive grains is 4.5 nm⁻² or more.

A lower limit of the average silanol group density is generally 0.

The number of silanol groups per unit surface area of the abrasive grains can be calculated by the Sears method using neutralization titration described in “Determination of Specific Surface Area of Colloidal Silica by Titration with Sodium Hydroxide,” Analytical Chemistry, 1956, 28 (12), pp. 1982-1983, by G. W. Sears. The calculation formula for the number of silanol groups is calculated by the following equation.

$$ρ = ( c \times a \times {N}_{A} ) / ( C \times S )$$

ρ: Number of silanol groups [count/nm^{2]}
c: Concentration of sodium hydrate solution used in titration [mol/L]
a: Amount of sodium hydrate solution having pH of 4 to 9 added dropwise [ml]
N_{A}: Avogadro's number (6.022×10²³ [count/mol])
C: Mass of silica [g]
S: BET specific surface area [nm²/g]

The number of silanol groups per unit surface area of the abrasive grains can be controlled by selection of the method for producing abrasive grains, or the like.

Moreover, the abrasive grains may be surface-modified as long as their average silanol group density is within the above-described range. In particular, colloidal silica with organic acid immobilized thereto is preferable. Such immobilization of the organic acid to surfaces of the colloidal silica contained in the polishing composition is made by, for example, chemically bonding functional groups of the organic acid with the surfaces of the colloidal silica. The organic acid is not immobilized to the colloidal silica just by allowing the colloidal silica and the organic acid to coexist. If immobilizing sulfonic acid that is a kind of such organic acid to the colloidal silica, for example, a method described in “Sulfonic acid-functionalized silica through quantitative oxidation of thiol groups,” Chem. Commun., 2003, 2, pp. 246-247 can be adopted. More specifically, by coupling a silane coupling agent having thiol groups such as 3-mercaptopropyltrimethoxysilane with the colloidal silica, and subsequently oxidizing the thiol groups with hydrogen peroxide, the colloidal silica with the sulfonic acid immobilized to its surface can be obtained. Alternatively, if immobilizing carboxylic acid to the colloidal silica, for example, a method described in “Novel Silane Coupling Agents Containing a Photolabile 2-Nitrobenzyl Ester for Introduction of a Carboxy Group on the Surface of Silica Gel,” Chemistry Letters, 2000, 29 (3), pp. 228-229, can be adopted. More specifically, by coupling a silane coupling agent containing photolabile 2-nitrobenzyl ester with the colloidal silica and subsequently irradiating the colloidal silica with light, colloidal silica with carboxylic acid immobilized to its surface can be obtained. Thus, in some embodiments, the abrasive is an anionic abrasive, which is surface-modified with one or more sulfonic acid groups. In further embodiments, such an anionic abrasive is an anionic silica abrasive, e.g., an anionic colloidal silica abrasive.

In some embodiments, the abrasive grains used in the present Working examples are surface-modified with sulfonic acid groups. Thus, the abrasive grains used in the present Working examples are colloidal silica with sulfonic acid immobilized to the surface thereof (sulfonated colloidal silica) obtained by coupling a silane coupling agent having thiol groups such as 3-mercaptopropyltrimethoxysilane with the colloidal silica, and subsequently oxidizing the thiol groups with hydrogen peroxide.

The amount of abrasive present in the disclosed polishing composition can vary. In some embodiments, the amount of abrasive in the polishing composition is about 0.01 wt % or more, about 0.05 wt % or more, about 0.1 wt % or more, about 0.2 wt % or more, about 0.25 wt % or more, about 0.5 wt % or more, about 0.75 wt % or more, about 1 wt % or more, about 2 wt % or more, about 3 wt % or more, or about 5 wt % or more. Alternatively, or in addition, the amount of abrasive in the polishing composition can be about 5 wt % or less, about 3 wt % or less, about 2 wt % or less, about 1 wt % or less, about 0.75 wt % or less, about 0.5 wt % or less, about 0.25 wt % or less, about 0.1 wt % or less, about 0.05 wt % or less, about 0.01 wt % or less, or about 0.05 wt % or less. In some embodiments, the amount of abrasive in the polishing composition can be in a range from about 0.01 wt % to about 5 wt %, about 0.05 wt % to about 3 wt %, from about 0.1 wt % to about 2.5 wt %, from about 0.25 wt % to about 2.0 wt %, or from about 0.5 wt % to about 2.0 wt %.

In some embodiments, the amount of abrasive has an effect on the properties of the polishing composition, such as Mo removal rate (RR). In some embodiments, the amount of abrasive is from about 0.5 wt % to about 2.0 wt %, from about 0.75 wt % to about 1.75 wt %, or from about 0.75 wt % to about 1.25 wt %. In an embodiment, the amount of abrasive is about 1.0 wt % with respect to the entire composition.

While the abrasive can be of any reasonable size, the size of the abrasive influences the smoothness of the finish obtained. Precision polishing operations materials such as optical components, plastics, metals, gemstones, semiconductor components, and the like typically involve the use of abrasives with smaller sizes. For example, compositions for use in connection with precision polishing involve suspensions of abrasives with smaller average particle sizes.

In some embodiments the abrasive is colloidal silica. In some embodiments, the abrasive substantially comprises colloidal silica. As used herein, “substantially” means that 95% by weight or more, preferably 98% by weight or more, more preferably 99% by weight or more of the particles constituting the abrasive are colloidal silica, and it includes that 100% by weight of the particles are colloidal silica. In some embodiments, organic acid is immobilized to the surface of the colloidal silica. In some embodiments, the surface of the colloidal silica is sulfonated.

The abrasive is suspended in the compositions disclosed herein and is colloidally stable. The term colloid refers to the suspension of abrasive particles in the liquid carrier. Colloidal stability refers to the maintenance of the suspension over time. In some embodiments, the suspension is stable for at least 1, 2, 3, 4, 5, 6, or 7 days. In some embodiments, the suspension is stable for at least 1 week, at least 2 weeks, at least 3 weeks, or at least 4 weeks.

In the context of this invention, an abrasive suspension is considered colloidally stable if, when the silica is placed into a 100-mL graduated cylinder and allowed to stand without agitation for a time of two hours, the difference between the concentration of particles in the bottom 50 mL of the graduated cylinder ([B] in terms of g/mL) and the concentration of particles in the top 50 mL of the graduated cylinder ([T] in terms of g/mL) divided by the total concentration of particles in the abrasive composition ([C] in terms of g/mL) is less than or equal to 0.5 (i.e., ([B]−[T])/[C]≤0.5). The value of ([B]−[T]/[C]) desirably is less than or equal to 0.3, and preferably is less than or equal to 0.1.

### 2. Oxidizer

The oxidizer added to the polishing composition has an action of oxidizing the surface of the polishing object and improves the polishing speed of the polishing object by the polishing composition. In some embodiments, the oxidizer is an iodine-containing oxidizer or a salt thereof. In some embodiments, the iodine-containing oxidizer is selected from the group consisting of elemental iodine (I₂), metal iodates, iodine oxides, iodine-containing acids, and a combination thereof.

Exemplary metal iodates include, but are not limited to, transition metal iodates. Exemplary metal transition iodates include copper iodates (Cu(IO₃)₂), iron iodates (Fe(IO₃)₃), bismuth iodates (BiO(IO₃)), manganese iodates (Mn(IO₃)₂), aluminum iodates (Al(IO₃)₃), silver iodates (AgIO₃), nickel iodates (Ni(IO₃)₂), chromium iodates (Cr(IO₃)₃), but are not limited thereto.

In some embodiments, the oxidizer is iodine-containing acid or a salt thereof, wherein the iodine-containing acid is selected from the group consisting of iodic acid (HIO₃ and/or HI₃O₈), periodic acid (H₅IO₆), metaperiodic acid (HIO₄), iodous acid (HIO₂), hypoiodous acid (HIO) and/or a salt thereof. In some embodiments, the iodine-containing acid is present in an alkali metal salt form, such as a sodium salt, potassium salt and/or cesium salt of the iodine-containing acid. In some embodiments, the iodine-containing acid is present in an alkaline earth metal salt form, such as a magnesium salt, calcium salt, and/or a barium salt of the iodine-containing acid. In some embodiments, the polishing composition comprises iodic acid or a salt thereof as an oxidizer. In some embodiments, the oxidizer is iodic acid or a salt thereof. In some embodiments, the polishing composition comprises potassium iodate as an oxidizer. In some embodiments, the oxidizer is potassium iodate (KIO₃). In some embodiments, the oxidizer comprises iodine-containing acid or a salt thereof, and in a preferable embodiment, the oxidizer comprises potassium iodate (KIO₃). In some embodiments, 80 wt % or more, 85 wt % or more, 90 wt % or more, 95 wt % or more, or 99 wt % or more of the oxidizer present in the polishing composition is constituted of iodine-containing acid or a salt thereof. In some embodiments, 80 wt % or more, 85 wt % or more, 90 wt % or more, 95 wt % or more, or 99 wt % or more of the oxidizer present in the polishing composition is constituted of potassium iodate (KIO₃).

In some embodiments, the oxidizer is an iodide oxide. Exemplary iodide oxides includes any chemical compound made of oxygen and iodine, e.g., diiodine oxide (I₂O), iodine monoxide (IO), iodine dioxide (IO₂), iodine tetroxide (I₂O₄), iodine pentaoxide (I₂O₅), and/or tetraiodine nonoxide (I₄O₉).

In some embodiments, the amount of oxidizer has an effect on the properties of the polishing composition, such as Mo removal rate (RR) and/or Mo static etching rate (SER). The amount of oxidizer may range from about 0.01 wt % to about 10 wt %, from about 0.01 wt % to about 5 wt %, from about 0.01 wt % to about 2.5 wt %, from about 0.01 wt % to about 1.5 wt %, from about 0.05 wt % to about 1.25 wt %, from about 0.05 wt % to about 1.0 wt %, or from about 0.05 wt % to about 1.0 wt %. In some embodiments, the oxidizer may range from about 0.05 wt % to about 1.2 wt %, from about 0.05 wt % to about 1.0 wt %, from about 0.07 wt % to about 1.25 wt %, from about 0.08 wt % to about 0.20 wt %, or about 0.1 wt %. In some embodiments, the oxidizer is present in an amount at about 0.01 wt % or more, about 0.05 wt % or more, about 0.1 wt % or more, about 0.25 wt % or more, about 0.5 wt % or more, about 0.75 wt % or more, or about 0.95 wt % or more. Alternatively, or in addition, the amount of oxidizer is about 5.0 wt % or less, about 4.0 wt % or less, about 3.0 wt % or less, about 2.0 wt % or less, about 1.5 wt % or less, about 1.25 wt % or less, about 1.0 wt % or less, about 0.2 wt % or less, or about 0.1 wt % or less. In some embodiments, the oxidizer is present in an amount of about 0.1 wt % or about 1.0 wt %. In some embodiments, the oxidizer is present in an amount of about 0.05 wt %. In some embodiments, the oxidizer is present in an amount of 5 wt % or less, 4 wt % or less, 3 wt % or less, 2 wt % or less, 1 wt % or less, less than 1 wt %, 0.9 wt % or less, 0.8 wt % or less, 0.7 wt % or less, 0.6 wt % or less, 0.5 wt % or less, 0.4 wt % or less, 0.3 wt % or less, or 0.2 wt % or less. In some embodiments, the oxidizer is present in an amount of 0.001 wt % or more, 0.003 wt % or more, 0.005 wt % or more, 0.01 wt % or more, 0.03 wt % or more, 0.05 wt % or more, or 0.07 wt % or more.

The percentage of oxidizer is measured with respect to the entire composition. Further, the percentage of oxidizer is measured as a Point Of Use (POU) composition. As used herein, the term “point of use” refers to a composition that is prepared and to be used in proximity to the planarization machine that supplies planarization fluid to an individual planarization machine for use in the CMP process.

### 3. Molybdenum Static Etching Rate Suppressors

The polishing composition described herein contains a first and a second molybdenum (Mo) static etching rate (SER) suppressor. In some embodiments, the first Mo SER suppressor and second Mo SER suppressor are not the same.

In some embodiments, the first Mo SER suppressor is a phosphate-containing polyethylene surfactant, a sulfate-containing polyethylene surfactant, or a combination thereof.

In some embodiments, the first Mo SER suppressor is a phosphate-containing polyethylene surfactant of Formula (I):

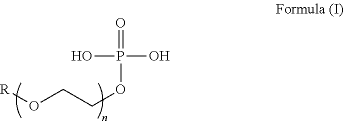

or a salt thereof; wherein n is an integer selected from about 1-500; and R is selected from a group consisting of aryl, (C1-C25)alkyl, and (C2-C25)alkenyl, wherein the salt is selected from an alkaline earth metal salt or an alkaline metal salt.

In some embodiments, the polishing composition comprises the phosphate-containing polyethylene surfactant of Formula (I) as the first Mo SER suppressor.

In some embodiments, the first Mo SER suppressor is a sulfate-containing polyethylene surfactant of Formula (II):

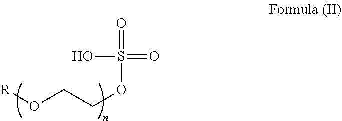

or a salt thereof; wherein n, R and the salt are the same as described above for Formula (I).

In some embodiments, n in Formula (I) or (II) is an integer selected from about 1-250, from about 1-200, from about 1-150, from about 1-100, from about 1-50, from about 1-40, from about 1-35, from about 1-30, from about 1-25, from about 1-20, from about 1-15, or from about 5-15. In some embodiments, n in Formula (I) or (II) is 7 or more, 8 or more, or 9 or more. In some embodiments, n in Formula (I) or (II) is 13 or less, 12 or less, or 11 or less.

In some embodiments, R in Formula (I) or (II) is (C1-C25)alkyl. In some embodiments, R in Formula (I) or (II) is (C1-C20)alkyl. In some embodiments, R in Formula (I) or (II) is (C5-C20)alkyl. In some embodiments, R in Formula (I) or (II) is (C5-C15)alkyl. In some embodiments, R in Formula (I) or (II) is (C10-C15)alkyl. In some embodiments, R in Formula (I) or (II) is an alkyl having C5 or more, C6 or more, C7 or more, C8 or more, C9 or more, C10 or more, C11 or more, or C12 or more. In some embodiments, R in Formula (I) or (II) is an alkyl having C20 or less, C19 or less, C18 or less, C17 or less, C16 or less, C15 or less, or C14 or less.

In some embodiments, R in Formula (I) or (II) is aryl. In some embodiments, R in Formula (I) or (II) is phenyl. In some embodiments, R in Formula (I) or (II) is naphthyl.

In some embodiments, R in Formula (I) or (II) is (C2-C25)alkenyl, wherein the alkenyl contains one double bond or more. In some embodiments, R in Formula (I) or (II) is (C8-C23)alkenyl. In some embodiments, R in Formula (I) or (II) is (C10-C22)alkenyl. In some embodiments, R in Formula (I) or (II) is (C12-C21)alkenyl. In some embodiments, R in Formula (I) or (II) is (C16-C20)alkenyl. In some embodiments, R in Formula (I) or (II) is an alkenyl having C10 or more, C11 or more, C12 or more, C13 or more, C14 or more, C15 or more, C16 or more or C17 or more. In some embodiments, R in Formula (I) or (II) is an alkenyl having C24 or less, C23 or less, C22 or less, C21 or less, C20 or less, or C19 or less.

In some embodiments, the phosphate-containing polyethylene surfactant of Formula (I) or the sulfate-containing polyethylene surfactant of Formula (II) is present in an alkaline earth metal salt form. Exemplary alkaline earth metal salts include, but are not limited to, a magnesium salt and a calcium salt.

In some embodiments, the phosphate-containing polyethylene surfactant of Formula (I) or the sulfate-containing polyethylene surfactant of Formula (II) is present in an alkali metal salt form. Exemplary alkali metal salts include, but are not limited to, a sodium salt and a potassium salt.

Exemplary phosphate-containing polyethylene surfactant disclosed herein include, but are not limited to, polyoxyethylene oleyl ether phosphate, polyoxyethylene phenyl ether phosphate, polyoxyethylene alkyl ether phosphate, polyoxyethylene tridecyl ether phosphate, and salts thereof (e.g., potassium salt of polyoxyethylene phenyl ether phosphate). Exemplary phosphate-containing polyethylene surfactant disclosed herein include polyoxyethylene alkenyl ether phosphate. More specifically, phosphate-containing polyethylene surfactant disclosed herein can be selected from the group consisting of polyoxyethylene (10) oleyl ether phosphate, potassium salt of polyoxyethylene (8) phenyl ether phosphate, polyoxyethylene (14) oleyl ether phosphate, polyoxyethylene (4-6) oleyl ether phosphate, polyoxyethylene (8) tridecyl ether phosphate, polyoxyethylene (12) tridecyl ether phosphate, and polyoxyethylene (10) tridecyl ether phosphate, wherein the number in parenthesis corresponds to variable n in Formula (I).

The number of polyoxyethylene chain can vary. This is also the case with Formula (I) and Formula (II). In some embodiments, the number can be 2 or more, 3 or more, 4 or more, 5 or more, 6 or more, 7 or more, 8 or more, or 9 or more. Large polyoxyetylene number improves the stability of polishing the composition. Alternatively, or in addition, the number of polyoxyethylene chain can be about 18 or less, 17 or less, 16 or less, 15 or less, 14 or less, 13 or less, 12 or less, or 11 or less. Small polyoxyetylene number improves the Mo(RR):Mo(SER) selectivity of the polishing composition. Exemplary sulfate-containing polyethylene surfactants disclosed herein include, but are not limited to, polyoxyethylene oleyl ether sulfate, polyoxyethylene phenyl ether sulfate, polyoxyethylene alkyl ether sulfate, polyoxyethylene tridecyl ether sulfate, and salts thereof (e.g., potassium salt of polyoxyethylene phenyl ether sulfate). Exemplary phosphate-containing polyethylene surfactant disclosed herein include polyoxyethylene alkenyl ether sulfate. More specifically, sulfate-containing polyethylene surfactant disclosed herein can be selected from the group consisting of polyoxyethylene (10) oleyl ether sulfate, potassium salt of polyoxyethylene (8) phenyl ether sulfate, polyoxyethylene (14) oleyl ether sulfate, polyoxyethylene (4-6) oleyl ether sulfate, polyoxyethylene (8) tridecyl ether sulfate, polyoxyethylene (12) tridecyl ether sulfate, and polyoxyethylene (10) tridecyl ether sulfate, wherein the number in parenthesis corresponds to the variable n in Formula (II).

The amount of the first molybdenum static etching rate suppressor present in the polishing composition can vary. In some embodiments, the amount of the first molybdenum static etching rate suppressor present in the polishing composition is in a range from about 0.01 wt % to about 0.5 wt %, about 0.01 wt % to about 0.25 wt %, from about 0.01 wt % to about 0.15 wt %, from 0.01 wt % to about 0.1 wt %, from about 0.01 wt % to about 0.07 wt %, or from about 0.03 wt % to about 0.07 wt %.

In some embodiments, the first molybdenum static etching rate suppressor is present in the polishing composition in an amount of 0.001 wt % or more, or 0.005 wt % or more. In some embodiments, the first molybdenum static etching rate suppressor is present in an amount of about 0.01 wt % or more, about 0.02 wt % or more, about 0.03 wt % or more, about 0.04 wt % or about 0.05 wt % or more. Alternatively, or in addition, the amount of first molybdenum static etching rate suppressor present in the polishing composition can be about 0.1 wt % or less, about 0.09 wt % or less, about 0.08 wt % or less, about 0.07 wt % or less, or about 0.05 wt % or less. In some embodiments, the first molybdenum static etching rate suppressor is present in an amount of about 0.05 wt %. In some embodiments, the first molybdenum static etching rate suppressor is present in the polishing composition in an amount of 5 wt % or less, 4 wt % or less, 3 wt % or less, 2 wt % or less, 1 wt % or less, 0.9 wt % or less, or 0.7 wt % or less. In some embodiments, the first molybdenum static etching rate suppressor is present in the polishing composition in an amount of 0.01 wt % or more, more than 0.01 wt %, 0.02 wt % or more, or more than 0.02 wt %. In some embodiments, the first molybdenum static etching rate suppressor is present in the polishing composition in an amount of 0.5 wt % or less, less than 0.5 wt %, 0.4 wt % or less, 0.3 wt % or less, or 0.2 wt % or less.

In some embodiments, the polishing composition comprises a basic amino acid as the second molybdenum static etching rate suppressor.

In some embodiments, the second molybdenum static etching rate suppressor present in the polishing composition is a basic amino acid. Exemplary basic amino acids include, but are not limited to, lysine, histidine, arginine and asparagine. In some embodiments, the polishing composition comprises at least one selected from the group consisting of arginine, histidine and lysine, as the second molybdenum static etching rate suppressor. In some embodiments, the basic amino acid is an L-amino acid (e.g., L-arginine). In some embodiments, the basic amino acid is a D-amino acid (e.g., D-arginine). In some embodiments, the basic amino acid is a mixture of L- and D-amino acids. In some embodiments, the polishing composition comprises arginine as the second molybdenum static etching rate suppressor. In some embodiments, when at least one of arginine and lysine is comprised as the second molybdenum static etching rate suppressor present in the polishing composition, reduction in Cl ion concentration would be more remarkable. In some embodiments, 80 wt % or more, 85 wt % or more, 90 wt % or more, 95 wt % or more, or 99 wt % or more of basic amino acid comprised in the polishing composition is constituted of arginine.

The amount of second molybdenum static etching rate suppressor present in the polishing composition can vary. In some embodiments, the amount of the second molybdenum static etching rate suppressor and the first molybdenum static etching rate suppressor are the same. In some embodiments, the amount of the second molybdenum static etching rate suppressor is less than the amount of the first molybdenum static etching rate suppressor. In some embodiments, the amount of second molybdenum static etching rate suppressor present in the polishing composition is in a range from about 0.01 wt % to about 0.5 wt %, about 0.01 wt % to about 0.25 wt %, from about 0.01 wt % to about 0.15 wt %, from 0.01 wt % to about 0.1 wt %, from about 0.01 wt % to about 0.07 wt %, or from about 0.03 wt % to about 0.07 wt %.

In some embodiments, the second molybdenum static etching rate suppressor is present in an amount of about 0.01 wt % or more, about 0.02 wt % or more, about 0.03 wt % or more, about 0.04 wt % or about 0.05 wt % or more. Alternatively, or in addition, the amount of second molybdenum static etching rate suppressor present in the polishing composition can be about 0.1 wt % or less, about 0.09 wt % or less, about 0.08 wt % or less, about 0.07 wt % or less, or about 0.05 wt % or less. In some embodiments, the second molybdenum static etching rate suppressor is present in an amount of about 0.05 wt %. In some embodiments, the second molybdenum static etching rate suppressor is present in the polishing composition in an amount of 0.001 wt % or more, or 0.005 wt % or more. In some embodiments, the second molybdenum static etching rate suppressor is present in the polishing composition in an amount of 2 wt % or less, 1 wt % or less, 0.9 wt % or less, 0.8 wt % or less, 0.7 wt % or less, 0.6 wt % or less, 0.5 wt % or less, 0.4 wt % or less, 0.3 wt % or less, or 0.2 wt % or less. In some embodiments, the second molybdenum static etching rate suppressor is present in the polishing composition in an amount of more than 0.01 wt %.

4. pH-Adjusting Agent

The polishing compositions described herein may also contain a pH-adjusting agent. The pH-adjusting agent is not particularly limited. However, the pH of the polishing composition has a direct effect on the effectiveness of the polishing composition.

In some embodiments, the pH-adjusting agent is an acidic compound. The choice of acid is not particularly limited provided that the strength of the acid is sufficient to lower the pH of the polishing composition of the present invention. The acidic pH adjuster may be an inorganic acid or an organic acid.

For example, and without limitation, such inorganic acids include hydrochloric acid, sulfuric acid, nitric acid, boric acid, carbonic acid, hypophosphorous acid, phosphorous acid, and phosphoric acid. In some embodiments, the pH-adjusting agent is phosphoric acid and/or nitric acid.

For example, and without limitation, such organic acids include formic acid, acetic acid, chloroacetic acid, propionic acid, butanoic acid, valeric acid, 2-methylbutyric acid, N-hexanoic acid, 3,3-dimethylbutanoic acid, 2-ethylbutanoic acid, 4-methylpentanoic acid, n-heptanoic acid, 2-methyl hexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citrate, citric acid, lactic acid, diglycolic acid, 2-furancarboxylic acid, 3-furancarboxylic acid, 2-tetrahydrofurancarboxylic acid, methoxyacetic acid, methoxyphenylacetic acid, and phenoxyacetic acid. Such organic acids also include, without limitation, organic sulfonic acid, such as methanesulfonic acid, ethanesulfonic acid, and isethionic acid.

In an alternate embodiment, the pH-adjusting agent may be a mixture of an acidic agent and basic agent (such as a buffer). In such embodiments, the base is not particularly limited and may be appropriately selected from an inorganic basic compound such as an alkali metal hydroxide, an alkaline earth metal hydroxide, various carbonates, bicarbonates and the like may be used. Such basic compounds may be used singly or in combination of two or more types thereof.

Specific examples of the alkali metal hydroxide include potassium hydroxide, sodium hydroxide, ammonium hydroxide, and the like. Specific examples of the carbonate and bicarbonate include ammonium hydrogen carbonate, ammonium carbonate, potassium hydrogen carbonate, potassium carbonate, sodium hydrogen carbonate, sodium carbonate and the like.

In an alternate embodiment, the pH-adjusting agent may be a buffer containing phosphates, acetates, borates, sulfonates, carboxylates, nitrates and the like. For example, in some embodiments, ammonium salts can be used as a buffer. Such ammonium salts include, but are not limited to, ammonium sulfates, ammonium acetates, and/or ammonium nitrates.

In some embodiments, the pH of the polishing composition is adjusted to a range from about 1.0 to about 5.0, from about 1.0 to about 4.5, from about 1.0 to about 4.0, from about 1.5 to about 4.0, or from about 2.0 to about 4.0. In some embodiments, the pH is less than about 4.5, less than about 4.2, less than about 4.0, less than about 3.0, less than about 2.5, less than about 2.25, less than about 2.0, or less than about 1.5. Alternatively, or in addition to, the pH is more than about 1.0, more than about 1.5, more than about 1.75, more than about 2.0, more than about 3.0 or more than about 3.75. In some embodiments, the pH is about 1.0, about 1.5, about 2.0, about 2.5, about 3.0, about 3.5, or is about 4.0. In some embodiments, the pH is about 2.0. In some embodiments, the pH of the polishing composition is adjusted to less than 4. In some embodiments, the pH of the polishing composition is adjusted to more than 0.5. In some embodiments, the pH of the polishing composition is more than 0.5 and less than 4.

The pH-adjusting agent may be present at a specific concentration range, regardless of pH. For example, in some embodiments, the amount of pH-adjusting agent is in a range from about 0.01 wt % to about 1 wt %, from about 0.02 wt % to about 0.5%, or from about 0.03 wt % to about 0.1 wt %. In some embodiments, the amount of pH-adjusting agent is in the from about 0.001 wt % to about 0.01 wt %, from about 0.001 wt % to about 0.008 wt %, from about 0.001 wt % to about 0.005 wt %, from about 0.001 wt % to about 0.003 wt %, or 0.002 wt %. In some embodiments, the amount of pH-adjusting agent is present in an amount of at least about 0.001 wt %, at least about 0.002 wt %, at least about 0.003 wt %, at least about 0.004 wt %, at least about 0.005 wt %, at least about 0.05 wt %, or at least about 0.5 wt %. In some embodiments, the pH-adjusting agent is present in an amount of less than about 1 wt %, less than about 0.1 wt %, less than about 0.01 wt %, or less than about 0.005 wt %. In some embodiments, the pH-adjusting agent is present in an amount that is about 0.002 wt %.

The pH of the polishing composition can be measured using any suitable method known in the art (for example, using ORION™ VERSA STAR PRO™ pH/ISE/conductivity/dissolved oxygen multiparameter bench-top meter from Thermo Fisher Scientific K.K.).

### 5. Water

In some embodiments, the polishing compositions disclosed herein contain a liquid carrier. In some embodiments, the liquid carrier is water. Ion exchanged water (deionized water), pure water, ultrapure water, distilled water and the like may be used as the water. In order to reduce the amount of unwanted components present in the water, the purity of water may be increased by operations such as removal of impurity ions with an ion exchange resin, removal of contaminants with a filter, and/or distillation.

In some embodiments, the water is relatively free of impurities. In some embodiments, the water contains less than about 10% w/w, about 9% w/w, about 8% w/w, about 7% w/w, about 6% w/w, about 5% w/w, about 4% w/w, about 3% w/w, about 2% w/w, about 1% w/w, about 0.9% w/w, about 0.8% w/w, about 0.7% w/w, about 0.6% w/w, about 0.5% w/w, about 0.4% w/w, about 0.3% w/w, or less than about 0.1% w/w of impurities based on the total weight of the water.

In some embodiments, 80 wt % or more, 85 wt % or more, 90 wt % or more, 95 wt % or more, 98 wt % or more, or 99 wt % or more of the liquid carrier comprised in the composition is water (the upper limit of water is 100 wt %).

### 6. Additional Components

In some embodiments, the polishing compositions disclosed herein may contain additional components such as chelating agents, biocides, surfactants, polymers, or co-solvents. Additionally, or alternatively, the compositions disclosed herein can include other additives as will be understood by those skilled in the art.

In some embodiments, the additional component may include a chelating agent. The term chelating agent is intended to mean any substance that in the presence of an aqueous solution chelates metals, such as copper. Non-limiting examples of chelating agents include inorganic acids, organic acids, amines, and amino acids such as glycine, alanine, citric acid, acetic acid, maleic acid, oxalic acid, malonic acid, phthalic acid, succinic acid, nitrilotriacetic acid, iminodiacetic acid, ethylenediamine, CDTA, and EDTA.

In some embodiments, the additional component may be a biocide. Non-limiting examples of biocides include hydrogen peroxide, quaternary ammonium compounds, and chlorine compounds. More specific examples of the quaternary ammonium compounds include, but are not limited to, methylisothiazolinone, tetramethylammonium chloride, tetraethylammonium chloride, tetrapropylammonium chloride, alkylbenzyldimethylammonium chloride, and alkylbenzyldimethylammonium hydroxide, wherein the alkyl chain ranges from 1 to about 20 carbon atoms. More specific examples of the chlorine compounds include, but are not limited to, sodium chlorite and sodium hypochlorite. Additional examples of biocides include biguanide, aldehydes, ethylene oxide, isothiazolinone, iodophor, Kordek™ MLX from DuPont (which is an aqueous composition of 2-methyl-4-isothiazolin-3-one), KATHON™ and NEOLENE™ product families that are commercially available from Dow chemicals, and the Preventol™ family from Lanxess. In an embodiment, the biocide is Kordek™ MLX. The amount of biocide used in the polishing composition may range from about 0.00005 wt % to 0.001 wt % or from about 0.0001 wt % to 0.0005 wt %. In some embodiments, the biocide is present in an amount about 0.0001 wt %, about 0.00013 wt %, or about 0.00015 wt %.

In another embodiment, the additional component may include a surfactant. The surfactants may be anionic, cationic, nonionic, or zwitterionic and may increase lubricity of the vehicle or compositions. Non-limiting examples of the surfactants are dodecyl sulfates, sodium salts or potassium salts, lauryl sulfates, secondary alkane sulfonates, alcohol ethoxylate, acetylenic diol surfactant, quaternary ammonium-based surfactants, amphoteric surfactants, such as betaines and amino acid derivatives-based surfactants, and any combination thereof. Examples of suitable commercially available surfactants include TRITON™, TERGITOL™, and the DOWFAX™ family of surfactants manufactured by Dow Chemicals. Suitable surfactants of surfactants may also include polymers comprising ethylene oxide (EO) and propylene oxide (PO) groups. An example of EO-PO polymer is TETRONIC™ 90R4 from BASF Chemicals. The amount of surfactant used in the polishing composition may range from about 0.0005 wt % to 0.15 wt %, preferably from 0.001 wt % to 0.05 wt %, and more preferably from 0.0025 wt % to 0.025 wt %.

In another embodiment, the additional component may include a polymer. The polymer may be vinyl polymer, polysaccharide polymer. Non-limiting examples of vinyl polymers include, but are not limited to, polyacrylic acid, polyvinyl, polyvinyl alcohol, polyvinylpyrrolidone. Non-limiting examples of polysaccharides include, but are not limited to, pullulan, dextrin.

In another embodiment, the additional component may include another solvent, termed a co-solvent. Non-limiting examples of co-solvents include, but are not limited to, alcohol (such as methanol or ethanol), ethyl acetate, tetrahydrofuran, alkanes, tetrahydrofuran, dimethylformamide, toluene, ketones (such as acetone), aldehydes, and esters. Other non-limiting examples of co-solvents include dimethyl formamide, dimethyl sulfoxide, pyridine, acetonitrile, glycols, and mixtures thereof. The co-solvent may be employed in various amounts, preferably from a lower limit of about 0.0001, 0.001, 0.01, 0.1, 0.5, 1, 5, or 10% (wt %) to an upper limit of about 0.001, 0.01, 0.1, 1, 5, 10, 15, 20, 25, or 35% (wt %).

As described herein, the polishing compositions have specific properties, which are greatly influenced by the components in the composition, both in type and amount. Thus, certain materials may need to be excluded from the composition in order to maintain the desired properties.

The polishing slurries of the invention can be prepared by any suitable technique, many of which are known to those skilled in the art. The polishing composition can be prepared in a batch or a continuous process. Generally, the polishing composition can be prepared by combining the components disclosed herein in any order. The term “component” as used herein includes individual ingredients (e.g., abrasive, first molybdenum static etching rate suppressor, second molybdenum static etching rate suppressor, oxidizer, and the like), as well as any combination of ingredients. For example, the first and second molybdenum static etching rate suppressors are dispersed in water followed by the addition of the abrasive, oxidizer, and any other additive material can be added, and mixed by any method that is capable of incorporating the components into the polishing composition. The pH can be further adjusted, if desired, at any suitable time by addition of an acid, base or a buffer, as needed.

Accordingly, the polishing compositions described herein have specific properties exemplified by their performance in molybdenum (Mo) removal rate and/or Mo static etching rate.

For the polishing compositions disclosed herein, the polishing compositions have a molybdenum (Mo) removal rate (RR) of at least ≥about 100 Å/min; at least ≥about 200 Å/min; at least ≥about 225 Å/min; at least ≥about 250 Å/min; at least ≥about 275 Å/min; at least ≥about 300 Å/min; at least ≥about 325 Å/min; at least ≥about 350 Å/min; at least ≥about 375 Å/min; at least ≥about 381 Å/min; at least ≥about 392 Å/min, or at least ≥about 400 Å/min. In some embodiments, the Mo removal rate is in a range from about 100 Å/min to about 500 Å/min; from about 250 Å/min to about 450 Å/min; from about 275 Å/min to about 425 Å/min; from about 300 Å/min to about 410 Å/min; from about 325 Å/min to about 400 Å/min; from about 350 Å/min to about 400 Å/min; from about 375 Å/min to about 400 Å/min; from about 380 Å/min to about 400 Å/min or from about 390 Å/min to about 400 Å/min. In some embodiments, the polishing compositions have the Mo removal rate in a range from about 380 Å/min to about 395 Å/min.

For the polishing compositions disclosed herein, the polishing compositions have a Mo static etching suppressor rate (SER) of less than about 100 Å/min; less than about 90 Å/min; less than about 80 Å/min; less than about 70 Å/min; less than about 60 Å/min; less than about 50 Å/min; less than about 40 Å/min; less than about 35 Å/min; less than about 30 Å/min; less than about 25 Å/min; less than about 20 Å/min; or less than about 10 Å/min. In some embodiments, the Mo static etching suppressor rate is in a range from about 1 Å/min to about 100 Å/min; from about 10 Å/min to about 80 Å/min; from about 20 Å/min to about 60 Å/min; from about 25 Å/min to about 50 Å/min; from about 25 Å/min to about 40 Å/min; or from about 27 Å/min to about 34 Å/min. In some embodiments, the Mo static etching suppressor rate is about 27 Å/min, about 30 Å/min, about 31 Å/min, about 32 Å/min, about 33 Å/min, about 34 Å/min, about 36 Å/min, or about 38 Å/min.

For the polishing compositions disclosed herein, the polishing compositions have a Mo(RR):Mo(SER) ratio of greater than about 10, about 11, about 12, about 13, about 14, or about 15. In some embodiments, the Mo(RR):Mo(SER) ratio is in a range from about 5 to about 20, from about 10 to about 15, from about 10 to about 14, from about 10 to about 13, from about 10 to about 12, or from about 11 to about 12. In some embodiments, the Mo(RR):Mo(SER) ratio is in a range from about 8 to about 18, from about 10 to about 16, from about 11 to about 15, from about 12 to about 15, from about 13 to about 15, or from about 14 to about 15.

Accordingly, as described herein, in some embodiments are polishing compositions comprising an anionic silica abrasive, a first molybdenum static etching rate suppressor, a second molybdenum static etching rate suppressor, and an oxidizer, wherein the first molybdenum static etching rate suppressor is a phosphate-containing polyethylene surfactant or a sulfate-containing polyethylene surfactant; and the second molybdenum static etching rate suppressor is a basic amino acid.

As in any embodiment above, the polishing composition wherein the first molybdenum static etching rate suppressor is a phosphate-containing polyethylene surfactant selected from the group consisting of polyoxyethylene oleyl ether phosphate, polyoxyethylene phenyl ether phosphate, polyoxyethylene alkyl ether phosphate, polyoxyethylene tridecyl ether phosphate, and salts thereof (e.g., potassium salt of polyoxyethylene phenyl ether phosphate).

As in any embodiment above, the polishing composition wherein the first molybdenum static etching rate suppressor is polyoxyethylene oleyl ether phosphate.

As in any embodiment above, the polishing composition wherein the second molybdenum static etching rate suppressor is selected from the group consisting of arginine, histidine, and lysine.

As in any embodiment above, the polishing composition wherein the second molybdenum static etching rate suppressor is arginine.

As in any embodiment above, the polishing composition wherein the first molybdenum static etching rate suppressor is present at a concentration from about 0.01 wt % to about 0.5 wt %.

As in any embodiment above, the polishing composition wherein the second molybdenum static etching rate suppressor is present at a concentration from about 0.01 wt % to about 0.5 wt %. As in any embodiment above, the polishing composition wherein the anionic silica abrasive is surface modified with one or more sulfonic acid groups.

As in any embodiment above, the polishing composition wherein the average primary particle size of the anionic silica abrasive ranges from about 10 nm to about 70 nm.

As in any embodiment above, the polishing composition wherein the average primary particle size of the anionic silica abrasive ranges from about 20 nm to about 50 nm.

As in any embodiment above, the polishing composition wherein the mean particle size of the anionic silica abrasive ranges from about 20 nm to about 120 nm.

As in any embodiment above, the polishing composition wherein the mean particle size of the anionic silica abrasive ranges from about 50 nm to about 80 nm.

As in any embodiment above, the polishing composition wherein the anionic abrasive is present in a concentration ranging from about 0.5 wt % to about 2 wt %.

As in any embodiment above, the polishing composition wherein the oxidizer is iodic acid or a salt thereof.

As in any embodiment above, the polishing composition wherein the oxidizer is potassium iodate.

As in any embodiment above, the polishing composition wherein the amount of oxidizer ranges from about 0.1 wt % to about 1 wt %.

As in any embodiment above, the polishing composition wherein the pH ranges from about 2 to about 4.

As in any embodiment above, the polishing composition wherein the pH-adjusting agent is an inorganic acid.

As in any embodiment above, the polishing composition wherein the pH-adjusting agent is phosphoric acid and/or nitric acid.

As in any embodiment above, the polishing composition wherein the composition comprises a chloride ion concentration of less than about 1 ppm.

As in any embodiment above, a polishing composition wherein the polishing composition is stable for a period of at least one week. In some embodiments, the pH of the composition remains unchanged after a period of at least one week. In another embodiment, the electrical conductivity (EC) of the composition remains unchanged after a period of at least one week. In some embodiments, the electrical conductivity is from greater than zero to about 0.50 mS/cm, from greater than zero to about 0.40 mS/cm, from greater than zero to about 0.30 mS/cm, from greater than zero to about 0.20 mS/cm, from greater than zero to about 0.10 mS/cm, from greater than zero to about 0.05 mS/cm, or from greater than zero to about 0.03 mS/cm. In some embodiments, the electrical conductivity is from no less than zero to about 3.00 mS/cm, from no less than zero to about 2.50 mS/cm, from no less than zero to about 2.00 mS/cm, from no less than zero to about 1.75 mS/cm, from no less than zero to about 1.50 mS/cm, from no less than zero to about 1.25 mS/cm, or from no less than zero to about 1.00 mS/cm. In some embodiments, the electrical conductivity is from about 0.03 mS/cm to about 3.0 mS/cm, from about 0.20 mS/cm to about 2.0 mS/cm, or from about 0.5 mS/cm to about 1.0 mS/cm. In some embodiments, the electrical conductivity is about 0.05, 0.10, 0.15, 0.20, 025, 0.30, 0.35, 0.40, 0.45, 0.50, 0.55, 0.60, 0.70, 0.75, 0.80, 0.85, 0.90, 1.00, 1.20, 1.40, 1.60, 1.80, 2.00, 2.20, 2.40, 2.60, 2.80 or 3.00 mS/cm.

Further, in some embodiments are polishing compositions comprising an anionic silica abrasive, a first molybdenum static etching rate suppressor, a second molybdenum static etching rate suppressor, and an oxidizer, wherein the anionic silica abrasive is surface-modified with one or more sulfonic acid groups, has an average primary particle size ranging from about 20 nm to about 50 nm, a mean particle size ranging from about 50 nm to about 80 nm, and is present in a concentration from about 0.5 wt % to about 2 wt %; the first molybdenum static etching rate suppressor is a phosphate-containing polyethylene surfactant selected from the group consisting of polyoxyethylene oleyl ether phosphate, potassium salt of polyoxyethylene phenyl ether phosphate, and polyoxyethylene tridecyl ether phosphate and is present at a concentration ranging from about 0.01 wt % to about 0.5 wt %; the second molybdenum static etching rate suppressor is a basic amino acid selected from the group consisting of arginine, histidine, and lysine and is present at a concentration ranging from about 0.01 wt % to about 0.5 wt %; and the oxidizer is iodic acid or a salt thereof and is present at a concentration ranging from about 0.1 wt % to about 1 wt %, and the polishing composition has a pH from about 2 to about 4.

In some embodiments, the polishing composition is provided, wherein the anionic silica abrasive is surface-modified with sulfonic acid groups, the first molybdenum static etching rate suppressor is a phosphate-containing polyethylene surfactant selected from the group consisting of polyoxyethylene oleyl ether phosphate, potassium salt of polyoxyethylene phenyl ether phosphate, and polyoxyethylene tridecyl ether phosphate, and is present at a concentration ranging from about 0.01 wt % to about 0.5 wt %; the second molybdenum static etching rate suppressor is a basic amino acid selected from the group consisting of arginine, histidine, and lysine and is present at a concentration ranging from about 0.01 wt % to about 0.5 wt %; and the oxidizer is iodic acid or a salt thereof and is present at a concentration ranging from about 0.1 wt % to about 1 wt %, and the polishing composition has a pH from about 2 to about 4.

In some embodiments, the polishing composition comprises potassium iodate as the oxidizer.

As in any embodiment above, the polishing composition further comprises a pH-adjusting agent present in a concentration from about 0.001 wt % to about 0.01 wt %.

As in any embodiment above, the polishing composition wherein the pH-adjusting agent is nitric acid and/or phosphoric acid.

As in any embodiment above, the polishing composition wherein the composition has a molybdenum removal rate of at least about 300 Å/min.

As in any embodiment above, the polishing composition wherein the composition has a molybdenum static etching rate of less than about 100 Å/min.

As in any embodiment above, the polishing composition wherein the composition has a molybdenum removal rate: molybdenum static etching rate selectivity of greater than 10.

### C. METHODS OF USING THE POLISHING COMPOSITIONS

The polishing compositions described herein are useful for polishing any suitable substrate. In some embodiments, the substrate to be polished can be any suitable substrate, which comprises at least one layer of molybdenum. Suitable substrates include, but are not limited to, flat panel displays, integrated circuits, memory or rigid disks, metals, interlayer dielectric (ILD) devices, semiconductors, microelectromechanical systems, ferroelectrics, and magnetic heads.

The substrate can further comprise at least one other layer, e.g., an insulating layer. The insulating layer can be a metal oxide, porous metal oxide, glass, organic polymer, fluorinated organic polymer, or any other suitable high- or low-K insulating layer. The insulating layer can comprise, consist essentially of, or consist of silicon oxide, SiN, or combinations thereof. The silicon oxide layer can comprise, consist essentially of, or consist of any suitable silicon oxide, many of which are known in the art. For example, the silicon oxide layer can comprise tetraethoxysilane (TEOS), high density plasma (HDP) oxide, borophosphosilicate glass (BPSG), high aspect ratio process (HARP) oxide, spin-on dielectric (SOD) oxide, chemical vapor deposition (CVD) oxide, plasma-enhanced tetraethyl orthosilicate (PETEOS), thermal oxide, or undoped silicate glass. In a specific embodiment, the silicon oxide layer is tetraethoxysilane (TEOS). The substrate can further comprise a metal layer. In a specific embodiment, the metal layer is molybdenum. In another specific embodiment, the silicon oxide layer is a thermal oxide. A thermal oxide can be a film made by oxidizing a Si substrate at around 110° C. in the air, which differs from a silicon oxide layer made from TEOS.

The subject matter disclosed herein also comprises a method for polishing a substrate with the polishing compositions described herein. The method of polishing a substrate comprises: (a) providing a substrate, (b) providing a polishing composition described herein, (c) applying the polishing composition to at least a portion of the substrate, and (d) abrading at least a portion of the substrate with the polishing composition to polish the substrate.

In the method of polishing a substrate, the polishing compositions disclosed herein have a molybdenum (Mo) removal rate (RR) of at least ≥about 100 Å/min; at least ≥about 200 Å/min; at least ≥about 225 Å/min; at least ≥about 250 Å/min; at least ≥about 275 Å/min; at least ≥about 300 Å/min; at least ≥about 325 Å/min; at least ≥about 350 Å/min; at least ≥about 375 Å/min; at least ≥about 381 Å/min; at least ≥about 392 Å/min; or at least ≥about 400 Å/min. In some embodiments, the Mo removal rate is in a range from about 100 Å/min to about 500 Å/min; from about 250 Å/min to about 450 Å/min; from about 275 Å/min to about 425 Å/min; from about 300 Å/min to about 410 Å/min; from about 325 Å/min to about 400 Å/min; from about 350 Å/min to about 400 Å/min; from about 375 Å/min to about 400 Å/min; from about 380 Å/min to about 400 Å/min or from about 390 Å/min to about 400 Å/min. In some embodiments, the Mo removal rate is in a range from about 380 Å/min to about 395 Å/min.

In the method of polishing a substrate, the polishing compositions disclosed herein have a Mo static etching suppressor rate (SER) of less than about 100 Å/min; less than about 90 Å/min; less than about 80 Å/min; less than about 70 Å/min; less than about 60 Å/min; less than about 50 Å/min; less than about 40 Å/min; less than about 35 Å/min; less than about 30 Å/min; less than about 25 Å/min; less than about 20 Å/min; or less than about 10 Å/min. In some embodiments, the Mo static etching suppressor rate is in a range from about 1 Å/min to about 100 Å/min; from about 10 Å/min to about 80 Å/min; from about 20 Å/min to about 60 Å/min; from about 25 Å/min to about 50 Å/min; from about 25 Å/min to about 40 Å/min; or from about 27 Å/min to about 34 Å/min. In some embodiments, the Mo static etching suppressor rate is about 27 Å/min, about 30 Å/min, about 31 Å/min, about 32 Å/min, about 33 Å/min, about 34 Å/min, about 36 Å/min, or about 38 Å/min.

In the method of polishing a substrate, the polishing compositions disclosed herein have a Mo(RR):Mo(SER) ratio of greater than about 10, about 11, about 12, about 13, about 14, or about 15. In some embodiments, the Mo(RR):Mo(SER) ratio is in a range from about 5 to about 20, from about 10 to about 15, from about 10 to about 14, from about 10 to about 13, from about 10 to about 12, or from about 11 to about 12. In some embodiments, the Mo(RR):Mo(SER) ratio is in a range from about 8 to about 18, from about 10 to about 16, from about 11 to about 15, from about 12 to about 15, from about 13 to about 15, or from about 14 to about 15.

Accordingly, as described herein, in some embodiments are methods of using the polishing compositions, where the methods comprise the steps of: a) providing the polishing composition described herein; b) providing a substrate, wherein the substrate comprises a molybdenum (Mo) containing layer; and c) polishing the substrate with the polishing composition to provide a polished substrate.

As in any embodiment above, a method wherein the substrate is a semiconductor.

As in any embodiment above, a method wherein the Mo removal rate (RR) is at least ≥about 300 Å/min.

As in any embodiment above, a method wherein the method results in a Mo static etching suppressor rate (SER) of less than about 100 Å/min.

As in any embodiment above, a method wherein the method results in Mo(RR):Mo(SER) ratio of greater than about 10.

The present invention encompasses the following aspects and embodiments.
1. A polishing composition comprising an anionic silica abrasive, a first molybdenum static etching rate suppressor, a second molybdenum static etching rate suppressor, and an oxidizer, wherein
the polishing composition comprises a phosphate-containing polyethylene surfactant as the first molybdenum static etching rate suppressor, and a basic amino acid as the second molybdenum static etching rate suppressor.
2. The polishing composition of 1., comprising, as the first molybdenum static etching rate suppressor, a phosphate-containing polyethylene surfactant of Formula (I):

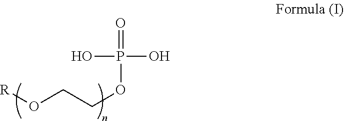

or a salt thereof; wherein n is an integer selected from about 1-500; R is selected from the group consisting of aryl, (C1-C25)alkyl, and (C2-C25)alkenyl; and wherein the salt is selected from an alkaline earth metal salt or an alkaline metal salt.
3. The polishing composition of 2., wherein the R is (C2-C25)alkenyl.
4. The polishing composition of any one of 1. to 3., comprising at least one selected from the group consisting of arginine, histidine, and lysine as the second molybdenum static etching rate suppressor.
5. The polishing composition of 4., comprising arginine as the second molybdenum static etching rate suppressor.
6. The polishing composition of any one of 1. to 5., wherein the first molybdenum static etching rate suppressor is present at a concentration of about 0.01 wt % to about 0.5 wt %.
7. The polishing composition of any one of 1. to 6., wherein the second molybdenum static etching rate suppressor is present at a concentration of about 0.01 wt % to about 0.5 wt %.
8. The polishing composition of any one of 1. to 7., wherein the oxidizer comprises iodic acid or a salt thereof.
9. The polishing composition of 8., wherein the oxidizer comprises potassium iodate.
10. The polishing composition of any one of 1. to 9., wherein the amount of the oxidizer ranges from about 0.1 wt % to about 1 wt %.
11. The polishing composition of any one of 1. to 10., wherein the pH ranges from about 2 to about 4.
12. The polishing composition of any one of 1. to 11., having a molybdenum removal rate: molybdenum static etching rate selectivity of greater than 10.
13. The polishing composition of any one of 1. to 12., comprising chloride ion concentration of less than about 1 ppm.
14. The polishing composition of 1., wherein the anionic silica abrasive is surface-modified with sulfonic acid groups, the first molybdenum static etching rate suppressor is a phosphate-containing polyethylene surfactant selected from the group consisting of polyoxyethylene oleyl ether phosphate, polyoxyethylene phenyl ether phosphate, and polyoxyethylene tridecyl ether phosphate, and a potassium salt thereof, and is present at a concentration ranging from about 0.01 wt % to about 0.5 wt %; the second molybdenum static etching rate suppressor is a basic amino acid selected from the group consisting of arginine, histidine, and lysine and is present at a concentration ranging from about 0.01 wt % to about 0.5 wt %; and the oxidizer is iodic acid or a salt thereof and is present at a concentration ranging from about 0.1 wt % to about 1 wt %, and the polishing composition has a pH from about 2 to about 4.
15. The polishing composition of 14., wherein the oxidizer is potassium iodate.

### D. EXAMPLES

The following preparations and examples are given to enable those skilled in the art to more clearly understand and to practice the present invention. They should not be considered as limiting the scope of the invention, but merely as being illustrative and representative. Unless otherwise stated, operations and measurements of physical properties and the like are conducted at 25° C.

In one aspect, disclosed are methods of making the polishing compositions. In another aspect are disclosed methods of using the polishing compositions to polish materials.

### Example 1

### Example 1: Polishing Conditions

### Materials and Tools Used:

Polishing conditions
Table Top Polisher
Platen rotation speed: 200 rpm
Head rotation speed: NA
Flow rate: 30 mL/min
Down force: 2 psi
Polishing time: 60 sec
Pad: medium hard pad
Dilution factor: 1×
1.0% KIO₃
DK Nano 2 kA Mo Blanket wafer (Si Substrate/thermal oxide/2000 Å Mo)

### Conditions for Static Etching Rate:

25° C. for 3 min.
Mo coupon size: 1.5 in x 1.5 in

### Instrumentation:

Table Top Polisher
Polishing pad: Fujibo H800,
Pad conditioner: 3M Nylon brush

### Polishing Recipe:

Down force: 2.0 psi,
Rotation: 200 rpm,
Slurry flow rate: 30 mL/min,
Polishing time: 60 sec

### Example 2

### Example 2: Evaluation of Various Polishing Compositions

For this study several molybdenum (Mo) static etching rate (SER) suppressors were investigated. Specifically, first Mo static etching rate suppressors A-M and second Mo static etching rate suppressors P, Q and R were screened, which are summarized in Table 1 below:

TABLE 1
Mo Static etching rate (SER) suppressor 1 and 2

| Type | Chemical Name |
|---|---|
| A | CAPRYLETH-6 CARBOXYLIC ACID |
| B | POLYVINYL ALCOHOL (PVA) (MW 10000) |
| C | 4-(2-HYDROXYETHYL)- 1-PIPERAZINE ETHANESULFONIC |
| | ACID |
| D | POLY ACRYLIC ACID (MW: 10000) |
| E | SULFONATED ACRYLIC POLYMER (MW: 10000) |
| F | POLYSTYRENESULFONIC ACID, SODIUM SALT, |
| | HOMOPOLYMER (MW: 10000) |
| G | POLYOXYETHYLENE (10) OLEYL ETHER PHOSPHATE |
| H | POLYOXYETHYLENE (8) PHENYL ether PHOSPHATE, |
| | K+ SALT |
| I | POLYOXYETHYLENE (14) OLEYL ETHER PHOSPHATE |
| J | POLYOXYETHYLENE (4-6) OLEYL ETHER PHOSPHATE |
| K | POLYOXYETHYLENE (8) TRIDECYL ETHER PHOSPHATE |
| L | POLYOXYETHYLENE (12) TRIDECYL ETHER PHOSPHATE |
| M | POLYOXYETHYLENE (10) TRIDECYL ETHER PHOSPHATE |
| P | L-ARGININE |
| Q | L-HISTIDINE |
| R | L-LYSINE |

“Mo Static etching rate (SER) suppressor 1” means first molybdenum static etching rate suppressor, and abbreviated as “Mo SER suppressor-01” in Table 2. The same is true for “Mo static etching rate (SER) suppressor 2”.

Various combinations of the first Mo SER and second Mo SER were investigated including their amounts while keeping the oxidizer, abrasive and pH adjuster constant for polishing Slurries 1-19. The Table 2 below shows that polishing Slurries 7-13 exhibit Mo removal rates that are greater than 350, while at the same time exhibit a Mo SER of 38 and below. The removal rate (polishing speed) can be measured by obtaining the thickness by an optical measurement device for film thickness (ASET-f5x: manufactured by KLA-Tencor Corporation) and dividing (thickness before polishing)−(thickness after polishing) by the polishing time.

In addition these slurries further exhibited a Cl ion concentration of less than 1 ppm. Table 2 shows that for Slurries 7-13, high Mo RR were observed when varying the first Mo static etching rate suppressor while remaining the second Mo static etching rate suppressor constant (i.e., P=L-arginine). Mo(RR):Mo(SER) selectivity ranged from about 10 to about 15 for Slurries 7-13. Slurries 7 and 12 exhibited the highest RR while at the same time exhibiting high Mo(RR): Mo(SER) selectivity. Providing supplemental explanations for this, though Slurries 9 and 13 have higher RR than that of Slurry 12, the selectivities for Slurries 9 and 13 are lower than the selectivity for Slurry 12, and thus Slurries 7 and 12 can be ranked as particularly preferable slurries in the present invention. Among Slurries 7 and 12, Slurry 7 is more preferable in terms of stability. Herein, “ppm” means “ppm by weight”.

Next, the amount of the first Mo static etching rate suppressor was varied. Slurries 7 and 16-18 show that high polishing rates can be obtained at concentrations ranging from about 0.01 to about 0.5, while exhibiting different Mo(RR):Mo(SER) selectivity. Similar observations were made when examining variations in concentration of the second Mo static etching rate suppressor (for example, comparing the Mo RR and Mo(RR):Mo(SER) selectivity of Slurries 7 and 19).

In addition, Slurries 7, 14 and 15 show the effects on Mo RR and Mo(RR):Mo(SER) selectivity when varying the second Mo static etching rate suppressor, which showed that both P and Q exhibit high Mo RR and high Mo(RR):Mo(SER) selectivity. However, Slurries 7 and 15 had lower chloride ion (Cl⁻) concentration compared to Slurry 14.

TABLE 2
Effect of Varied Mo Suppressors

| | | Abrasive | | | | Oxidizer | Mo SER | |
|---|---|---|---|---|---|---|---|---|
| Slurry | Abrasive | conc. | pH | | Oxidizer | conc. | suppressor | Concentration |
| number | type | [wt %] | adjuster | pH | type | [wt %] | 01 | [wt %] |
| 1 | F | 1 | Phosphoric acid | 2 | Potassium iodate | 0.1 | A | 0.05 |
| 2 | F | 1 | Phosphoric acid | 2 | Potassium iodate | 0.1 | B | 0.05 |
| 3 | F | 1 | Phosphoric acid | 2 | Potassium iodate | 0.1 | C | 0.05 |
| 4 | F | 1 | Phosphoric acid | 2 | Potassium iodate | 0.1 | D | 0.05 |
| 5 | F | 1 | Phosphoric acid | 2 | Potassium iodate | 0.1 | E | 0.05 |
| 6 | F | 1 | Phosphoric acid | 2 | Potassium iodate | 0.1 | F | 0.05 |
| 7 | F | 1 | Phosphoric acid | 2 | Potassium iodate | 0.1 | G | 0.05 |
| 8 | F | 1 | Phosphoric acid | 2 | Potassium iodate | 0.1 | H | 0.05 |
| 9 | F | 1 | Phosphoric acid | 2 | Potassium iodate | 0.1 | I | 0.05 |
| 10 | F | 1 | Phosphoric acid | 2 | Potassium iodate | 0.1 | J | 0.0S |
| 11 | F | 1 | Phosphoric acid | 2 | Potassium iodate | 0.1 | K | 0.05 |
| 12 | F | 1 | Phosphoric acid | 2 | Potassium iodate | 0.1 | L | 0.05 |
| 13 | F | 1 | Phosphoric acid | 2 | Potassium iodate | 0.1 | M | 0.05 |
| 14 | F | 1 | Phosphoric acid | 2 | Potassium iodate | 0.1 | G | 0.05 |
| 15 | F | 1 | Phosphoric acid | 2 | Potassium iodate | 0.1 | G | 0.05 |
| 16 | F | 1 | Phosphoric acid | 2 | Potassium iodate | 0.1 | G | 0.01 |
| 17 | F | 1 | Phosphoric acid | 2 | Potassium iodate | 0.1 | G | 0.02 |
| 18 | F | 1 | Phosphoric acid | 2 | Potassium iodate | 0.1 | G | 0.5 |
| 19 | F | 1 | Phosphoric acid | 2 | Potassium iodate | 0.1 | G | 0.05 |

| | Mo SER | | | Mo | | | Cl |
|---|---|---|---|---|---|---|---|
| Slurry | suppressor | Concentration | Mo RR | SER_40 deg | | | conc. |
| number | 02 | [wt %] | [Å/min] | C. [Å/min] | Selectivity | Stability | [ppm] |
| 1 | P | 0.05 | 188 | 99 | 1.9 | A | <1 |
| 2 | P | 0.05 | 401 | [symbol] | 0.5 | A | <1 |
| 3 | P | 0.05 | [symbol] | 427 | 0.8 | A | <1 |
| 4 | P | 0.05 | 312 | 88 | 3.5 | A | <1 |
| 5 | P | 0.05 | [symbol] | 92 | 1.8 | A | <1 |
| 6 | P | 0.05 | 174 | [symbol] 3 | 2.1 | A | <1 |
| 7 | P | 0.05 | [symbol] | 26 | 15.6 | A | <1 |
| 8 | P | 0.05 | 371 | 31 | 12.0 | A | <1 |
| 9 | P | 0.05 | 391 | 38 | 10. [symbol] | A | <1 |
| 10 | P | 0.05 | [symbol] | 24 | 15.0 | C | <1 |
| 11 | P | 0.05 | 377 | 27 | 14.0 | C | <1 |
| 12 | P | 0.05 | 389 | 30 | 13.0 | B | <1 |
| 13 | P | 0.05 | 391 | 31 | 12.6 | B | <1 |
| 14 | Q | 0.05 | 399 | 27 | 14.8 | A | 2.0 |
| 15 | R | 0.05 | 400 | 31 | 12.9 | A | 1.0 |
| 16 | P | 0.05 | 394 | 34 | 11.6 | A | <1 |
| 17 | P | 0.05 | 393 | 32 | 12. [symbol] | A | <1 |
| 18 | P | 0.05 | [symbol] | 27 | 14.1 | B | <1 |
| 19 | P | 0.01 | 394 | 33 | [symbol] | A | <1 |

[symbol]

indicates data missing or illegible when filed

Next, the Mo static etching rate (SER) and removal rate (RR) of polishing slurries with polyoxyethylene (10) oleyl ether phosphate as a first Mo SER and L-arginine as a second Mo SER were investigated by varying pH values and oxidizer concentrations (e.g., Slurries 7, 21 and 22). High Mo RR and good Mo(RR):Mo(SER) selectivity was observed for Slurries 7, and 21, showing that the pH and amount of oxidizer can vary while still maintaining beneficial polishing properties. Slurry 23 also exhibited a high Mo(RR):Mo(SER) selectivity, however, the chloride ion concentration was <2 ppm. Histidine is predominantly present in the form of a hydrochloride industrially, and lysine is likely to be contaminated with chloride ion as impurities in the manufacturing process. Since chloride ion causes corrosion of the polishing apparatus and the like, thus causing generation of damages, and thus the presence of chloride ion is undesirable. Therefore, chloride ion is preferably present at less than 2 ppm by weight, or less than 1 ppm by weight in the polishing composition. Alternatively, it is preferable to control the content of chloride ion to be within such range.

### Evaluation of Stability

The change in absolute value between the pH immediately after preparation of the polishing slurry prepared under the environment at 25° C. and the pH of the polishing slurry after storing the polishing slurry by leaving it to stand for 1 week under the environment at 25° C. was measured.
A: The change in absolute value of the pH is 0.3 or less,
B: The change in absolute value of the pH is more than 0.3 and 0.6 or less,
C: The change in absolute value of the pH is more than 0.6.

The pH of polishing slurries was measured using ORION™ VERSA STAR PRO™ pH/ISE/conductivity/dissolved oxygen multiparameter bench-top meter from Thermo Fisher Scientific K.K.

TABLE 3A
Molybdenum static etching rate (SER) and removal rate (RR) with two SER suppressors.

| | | Abrasive | | | | Oxidizer | Mo SER | |
|---|---|---|---|---|---|---|---|---|
| Slurry | Abrasive | conc. | pH | | Oxidizer | conc. | suppressor | Concentration |
| number | type | [wt %] | adjuster | pH | type | [wt %] | 01 | [wt %] |
| 20 | F | 1 | Phosphoric | 2 | Potassium | 0.1 | N/A | N/A |
| | | | acid | | iodate | | | |
| 7 | F | 1 | Phosphoric | 2 | Potassium | 0.1 | G | 0.05 |
| | | | acid | | iodate | | | |
| 21 | F | 1 | Phosphoric | 2 | Potassium | 1 | G | 0.05 |
| | | | acid | | iodate | | | |
| 22 | F | 1 | Phosphoric | 0.5 | Potassium | 0.1 | G | 0.05 |
| | | | acid | | iodate | | | |
| 23 | F | 1 | Phosphoric | 4 | Potassium | 0.1 | G | 0.05 |
| | | | acid | | iodate | | | |

| | Mo SER | | | Mo | | | Cl |
|---|---|---|---|---|---|---|---|
| Slurry | suppressor | Concentration | Mo RR | SER_40 deg | | | conc. |
| number | 02 | [wt %] | [Å/min] | C. [Å/min] | Selectivity | Stability | [ppm] |
| 20 | N/A | N/A | 524 | 782 | 0.7 | A | <1 |
| 7 | P | 0.05 | 399 | 26 | 15.6 | A | <1 |
| 21 | P | 0.05 | 401 | 28 | 14.3 | A | <1 |
| 22 | P | 0.05 | 421 | 31 | 13.6 | A | <1 |
| 23 | P | 0.05 | 311 | 22 | 14.3 | A | <2 |

The above table further shows that polishing Slurries 7 and 21 exhibited high Mo removal rates (RR) and high Mo(RR):Mo(SER) selectivity. By contrast, Slurry-20, which contains no Mo SER suppressor, exhibited high Mo RR and SER (and essentially no Mo(RR):Mo(SER) selectivity), which demonstrates that beneficial polishing properties are exhibited by the disclosed polishing slurries containing a first and a second Mo SER suppressor.

In addition, a series of various abrasives A-G were examined, which differed in properties such as their average primary particle size, average secondary particle size (an average mean particle size) and surface modification. See Table 3B below.

TABLE 4
Abrasive Type

| | PPS | MPS | | Silanol group density |
|---|---|---|---|---|
| Type | [nm] | [nm] | Surface Modification | [count/nm²] |
| A | 10 | 23 | None | 5.1 |
| B | 20 | 46 | None | 5.5 |
| C | 35 | 70 | None | 6.1 |
| D | 10 | 23 | Anionic (sulfonated) | 4.8 |
| E | 20 | 46 | Anionic (sulfonated) | 5.1 |
| F | 35 | 70 | Anionic (sulfonated) | 5.3 |
| G | 70 | 120 | Anionic (sulfonated) | 5.5 |

As is shown in Table 4 below, Slurries 7 and 24-29 were screened for their Mo RR, Mo SER, and Mo(RR):Mo(SER) selectivity, which contained the abrasives shown in Table 3B.

TABLE 4
Effects of various abrasives

| | | Abrasive | | | | Oxidizer | Mo SER | |
|---|---|---|---|---|---|---|---|---|
| Slurry | Abrasive | conc. | pH | | Oxidizer | conc. | suppressor | Concentration |
| number | type | [wt %] | adjuster | pH | type | [wt %] | 01 | [wt %] |
| 24 | A | 1 | Phosphoric | 2 | Potassium | 0.1 | G | 0.05 |
| | | | acid | | iodate | | | |
| 25 | B | 1 | Phosphoric | 2 | Potassium | 0.1 | G | 0.05 |
| | | | acid | | iodate | | | |
| 26 | C | 1 | Phosphoric | 2 | Potassium | 0.1 | G | 0.05 |
| | | | acid | | iodate | | | |
| 27 | D | 1 | Phosphoric | 2 | Potassium | 0.1 | G | 0.05 |
| | | | acid | | iodate | | | |
| 28 | E | 1 | Phosphoric | 2 | Potassium | 0.1 | G | 0.05 |
| | | | acid | | iodate | | | |
| 7 | F | 1 | Phosphoric | 2 | Potassium | 0.1 | G | 0.05 |
| | | | acid | | iodate | | | |
| 29 | G | 1 | Phosphoric | 2 | Potassium | 0.1 | G | 0.05 |
| | | | acid | | iodate | | | |

| | Mo SER | | | Mo | | |
|---|---|---|---|---|---|---|
| Slurry | suppressor | Concentration | Mo RR | SER_40 deg | | |
| number | 02 | [wt %] | [Å/min] | C. [Å/min] | Selectivity | Stability |
| 24 | P | 0.05 | 341 | 27 | 12.6 | C |
| 25 | P | 0.05 | 376 | 28 | 13.4 | C |
| 26 | P | 0.05 | 355 | 26 | 13.7 | C |
| 27 | P | 0.05 | 345 | 27 | 12.8 | A |
| 28 | P | 0.05 | 373 | 27 | 13.8 | A |
| 7 | P | 0.05 | 399 | 26 | 15.6 | A |
| 29 | P | 0.05 | 391 | 27 | 14.5 | A |

As is illustrated in Table 4, Slurries 24, 25 and 26, which contained abrasives with no surface modification, were less stable compared to Slurries 7 and 27-29, which contained surface-modified abrasives. In addition, Slurries 7, 28 and 29 exhibited high Mo RR and high Mo(RR):Mo(SER) selectivity. From this data, it can be seen that slurries employing surface-modified abrasives, such as F and G, exhibit beneficial polishing properties. Therefore, abrasive F was used when investigating other components in the polishing slurries as already described above.

It will be apparent to those skilled in the art that various modifications and variations can be made in the present invention without departing from the scope or spirit of the invention. Other aspects of the invention will be apparent to those skilled in the art from consideration of the specification and practice of the invention disclosed herein. It is intended that the specification and examples be considered as exemplary only, with a true scope and spirit of the invention being indicated by the following claims.

The present application is based on U.S. provisional patent application No. 63/537,635 filed on Sep. 11, 2023, the disclosed content of which is herein incorporated by reference in its entirety.

1. A polishing composition comprising an anionic silica abrasive, a first molybdenum static etching rate suppressor, a second molybdenum static etching rate suppressor, and an oxidizer, wherein the polishing composition comprises
a phosphate-containing polyethylene surfactant as the first molybdenum static etching rate suppressor, and
a basic amino acid as the second molybdenum static etching rate suppressor.

2. The polishing composition of claim 1, comprising, as the first molybdenum static etching rate suppressor, a phosphate-containing polyethylene surfactant of Formula (I): 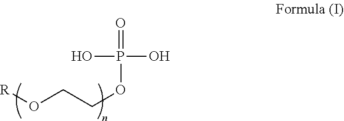
or a salt thereof; wherein
n is an integer selected from about 1-500;
R is selected from the group consisting of aryl, (C1-C25)alkyl, and (C2-C25)alkenyl;
and wherein the salt is selected from an alkaline earth metal salt or an alkaline metal salt.

3. The polishing composition of claim 2, wherein the R is (C2-C25)alkenyl.

4. The polishing composition of claim 1, comprising at least one selected from the group consisting of arginine, histidine, and lysine as the second molybdenum static etching rate suppressor.

5. The polishing composition of claim 4, comprising arginine as the second molybdenum static etching rate suppressor.

6. The polishing composition of claim 1, wherein the first molybdenum static etching rate suppressor is present at a concentration of about 0.01 wt % to about 0.5 wt %.

7. The polishing composition of claim 1, wherein the second molybdenum static etching rate suppressor is present at a concentration of about 0.01 wt % to about 0.5 wt %.

8. The polishing composition of claim 1, wherein the oxidizer comprises iodic acid or a salt thereof.

9. The polishing composition of claim 8, wherein the oxidizer comprises potassium iodate.

10. The polishing composition of claim 1, wherein the amount of the oxidizer ranges from about 0.1 wt % to about 1 wt %.

11. The polishing composition of claim 1, wherein the pH ranges from about 2 to about 4.

12. The polishing composition of claim 1, having a molybdenum removal rate: molybdenum static etching rate selectivity of greater than 10.

13. The polishing composition of claim 1, wherein the composition comprises a chloride ion concentration of less than about 1 ppm.

14. The polishing composition of claim 1, wherein
the anionic silica abrasive is surface-modified with sulfonic acid groups,
the first molybdenum static etching rate suppressor is a phosphate-containing polyethylene surfactant selected from the group consisting of polyoxyethylene oleyl ether phosphate, polyoxyethylene phenyl ether phosphate, and polyoxyethylene tridecyl ether phosphate, and a potassium salt thereof, and is present at a concentration ranging from about 0.01 wt % to about 0.5 wt %,
the second molybdenum static etching rate suppressor is a basic amino acid selected from the group consisting of arginine, histidine, and lysine and is present at a concentration ranging from about 0.01 wt % to about 0.5 wt %,
the oxidizer is iodic acid or a salt thereof and is present at a concentration ranging from about 0.1 wt % to about 1 wt %, and
the polishing composition has a pH from about 2 to about 4.

15. The polishing composition of claim 14, wherein the oxidizer is potassium iodate.
